(19) United States
(12) Patent Application Publication
(10) Pub. No.: US 2026/0143578 A1
(43) Pub. Date: May 21, 2026

(54) DRIFT TUBE ASSEMBLY FOR LINEAR ACCELERATORS

(71) Applicant: Applied Materials, Inc., Santa Clara, CA (US)

(72) Inventors: Jason M. Schaller, Austin, TX (US); Aaron P. Webb, Austin, TX (US); David T. Blahnik, Round Rock, TX (US); Luke Bonecutter, Cedar Park, TX (US); Mukesh CS, Chitradurga (IN)

(73) Assignee: Applied Materials, Inc., Santa Clara, CA (US)

(21) Appl. No.: 18/955,176

(22) Filed: Nov. 21, 2024

(51) Int. Cl. H05H 7/22; C23C 14/48

(52) U.S. Cl. CPC H05H 7/22; C23C 14/48; H05H 2007/222; H05H 2277/12

(57) ABSTRACT

A drift tube assembly including a drift tube having a cylindrical main body and a mounting cuff extending from the main body and defining a mounting socket. A mounting device is disposed within the mounting socket and includes an inner sleeve having a tapered exterior surface, a tubular outer sleeve surrounding the inner sleeve and having a tapered interior surface engaging the exterior surface of the inner sleeve, and a nut surrounding the outer and inner sleeves and including a flange extending into a groove formed in an exterior of the outer sleeve, the nut threadedly engaging a threaded portion of the exterior surface of the inner sleeve. A mounting rod extends into a passthrough of the inner sleeve of the mounting device. Tightening the nut causes the inner sleeve to tighten against the mounting rod and causes the outer sleeve to tighten against the mounting cuff.

### FIELD OF THE DISCLOSURE

The present disclosure relates generally to ion implantation systems, and more particularly to mounting arrangements for drift tubes in linear accelerators of ion implantation systems.

### BACKGROUND OF THE DISCLOSURE

In ion implantation systems, linear accelerators (LINACs) are used to accelerate ions to high energies (e.g., 1 MeV or greater) before the ions are implanted into a target material, such as a semiconductor wafer. A typical LINAC includes a series of cylindrical electrodes, commonly referred to as “drift tubes,” that assist in transmitting and accelerating ions to increasingly higher energies along the succession of drift tubes. The ions, transmitted in the form of an “ion beam,” are accelerated by oscillating radio-frequency (RF) electric fields that push the ions in the direction of motion. However, the electric fields alternate between accelerating and decelerating phases. To ensure that the ions are only accelerated, the drift tubes are used to shield the ions from the decelerating phases of the oscillating fields. The ions thus “drift” through the drift tubes and are accelerated in gaps between the drift tubes.

In a typical LINAC, a drift tube is suspended in a vacuum chamber located in a beamline of an ion implantation system. The drift tube is connected to the end of a mounting rod which is in-turn connected to a so-called “feedthrough” structure that extends outside of the vacuum chamber. The feedthrough is used to convey electrical signals, power, and/or fluids (e.g., cooling water or gases) between the outside environment and the interior of the vacuum chamber while maintaining a vacuum seal therebetween. The feedthrough thus serves as a connection point for electrical, mechanical, and/or fluid systems that interact with components inside the LINAC, such as electromagnetic coils, sensors, and cooling systems, without compromising the vacuum conditions essential for efficient ion acceleration.

When a drift tube is installed in a LINAC, it is important that the drift tube be precisely aligned relative to the beamline of an ion implantation system to ensure efficient ion acceleration and to minimize energy losses. Additionally, since drift tubes are susceptible to overheating as a result of ionic bombardment, it is important to provide robust thermal coupling between a drift tube its mounting rod so that heat can be efficiently carried away from the drift tube.

In traditional LINAC configurations, mechanical fasteners (e.g., screws, pins, friction washers, etc.) are typically used to connect drift tubes to their mounting rods. However, such fasteners generally do not provide a strong enough connection to resist external forces that can twist or translate the drift tubes out of their nominal precise positions and orientations. Moreover, mechanical fasteners provide relatively weak thermal coupling between the drift tubes and the mounting rods. Since the mounting rods operate to carry heat away from the drift tubes, weak thermal coupling may be detrimental to heat transfer and may make the drift tubes prone to overheating.

With respect to these and other considerations, the present disclosure is provided.

### SUMMARY OF THE DISCLOSURE

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

A drift tube assembly according to an embodiment of the present disclosure may include a drift tube having a cylindrical main body and a mounting cuff extending from a sidewall of the main body, the mounting cuff defining a mounting socket. A mounting device is disposed within the mounting socket of the drift tube and includes a frustoconical inner sleeve having a tapered exterior surface and defining a passthrough, a tubular outer sleeve radially surrounding the inner sleeve and having a tapered interior surface parallel to, and radially engaging, the exterior surface of the inner sleeve, and a nut radially surrounding upper portions of the outer sleeve and the inner sleeve and including a radially inwardly extending flange extending into an annular groove formed in an exterior of the outer sleeve, the nut further having a threaded interior surface threadedly engaging a threaded upper portion of the exterior surface of the inner sleeve. A mounting rod extends into the passthrough of the inner sleeve of the mounting device, and tightening the nut causes the inner sleeve to exert a radially-inwardly directed force on the mounting rod and causes the outer sleeve to exert a radially-outwardly directed force on the mounting cuff to couple the drift tube to the mounting rod.

A drift tube assembly according to another embodiment of the present disclosure includes a drift tube having a cylindrical main body and a fastening stem extending from a sidewall of the main body, the fastening stem including a cylindrical base portion having a threaded exterior surface and a gripping portion extending from a top of the base portion, the gripping portion having a tapered exterior surface and defining a mounting socket. The drift tube assembly further includes a mounting device defining a passthrough and having an interior surface with a threaded lower portion threadedly engaging the threaded exterior surface of the base portion, the interior surface further including a tapered portion extending from a top of the lower portion, the tapered portion parallel to, and radially engaging, the tapered exterior surface of the gripping portion. The drift tube assembly further includes a mounting rod extending through the passthrough of the mounting device and into the mounting socket of the gripping portion, wherein tightening the mounting device onto the fastening stem causes the gripping portion to exert a radially-inwardly directed force on the mounting rod to couple the drift tube to the mounting rod.

A drift tube assembly according to another embodiment of the present disclosure includes a drift tube having a cylindrical main body and a fastening stem extending from a sidewall of the main body. The drift tube assembly further includes a mounting rod terminating in a collet including a cylindrical base portion having a threaded exterior surface and a frustoconical gripping portion extending from a bottom of the base portion, the gripping portion having a tapered exterior surface and defining a mounting socket. The drift tube assembly further includes a mounting device including a nut defining a passthrough and having an interior surface with a threaded upper portion threadedly engaging the threaded exterior surface of the base portion, the interior surface further including a tapered portion extending from a bottom of the upper portion, the tapered portion parallel to, and radially engaging, the tapered exterior surface of the gripping portion, wherein the fastening stem extends through the passthrough of the mounting device and into the mounting socket of the gripping portion, and wherein tightening the mounting device onto the collet causes the gripping portion to exert a radially-inwardly directed force on the mounting rod to couple the drift tube to the mounting rod.

### BRIEF DESCRIPTION OF THE DRAWINGS

The accompanying drawings illustrate exemplary approaches of the disclosure, including the practical application of the principles thereof, as follows:

FIG. 1 is a schematic view illustrating an ion implanter in accordance with embodiments of the present disclosure;

FIG. 2A is a perspective view illustrating a drift tube assembly in accordance with embodiments of the present disclosure;

FIG. 2B is an exploded view illustrating the drift tube assembly shown in FIG. 2A;

FIG. 2C is a cross-sectional view illustrating the drift tube assembly shown in FIG. 2A;

FIG. 2D is an exploded cross-sectional view illustrating the drift tube assembly shown in FIG. 2A; and

FIG. 3 is a bottom view illustrating a mounting device of the drift tube assembly shown in FIG. 2A;

FIG. 4A is a perspective view illustrating a drift tube assembly in accordance with another embodiment of the present disclosure;

FIG. 4B is an exploded view illustrating the drift tube assembly shown in FIG. 4A;

FIG. 4C is a cross-sectional view illustrating the drift tube assembly shown in FIG. 4A;

FIG. 5A is a perspective view illustrating a drift tube assembly in accordance with another embodiment of the present disclosure;

FIG. 5B is an exploded view illustrating the drift tube assembly shown in FIG. 5A; and

FIG. 5C is a cross-sectional view illustrating the drift tube assembly shown in FIG. 5A;

FIG. 6A is a perspective view illustrating a drift tube assembly in accordance with another embodiment of the present disclosure;

FIG. 6B is an exploded view illustrating the drift tube assembly shown in FIG. 6A; and

FIG. 6C is a cross-sectional view illustrating the drift tube assembly shown in FIG. 6A.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, wherein some exemplary embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Furthermore, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

The present disclosure is directed to an improved configuration for a linear accelerator (LINAC) of an ion implantation system, which may also be referred to herein as an “ion implanter” for the sake of brevity. More specifically, various embodiments of the present disclosure are directed to an improved mechanical coupling and associated method for connecting certain components of a LINAC to one another. The improved coupling and method my provide various advantages over known configurations and methods as will be described in greater detail below.

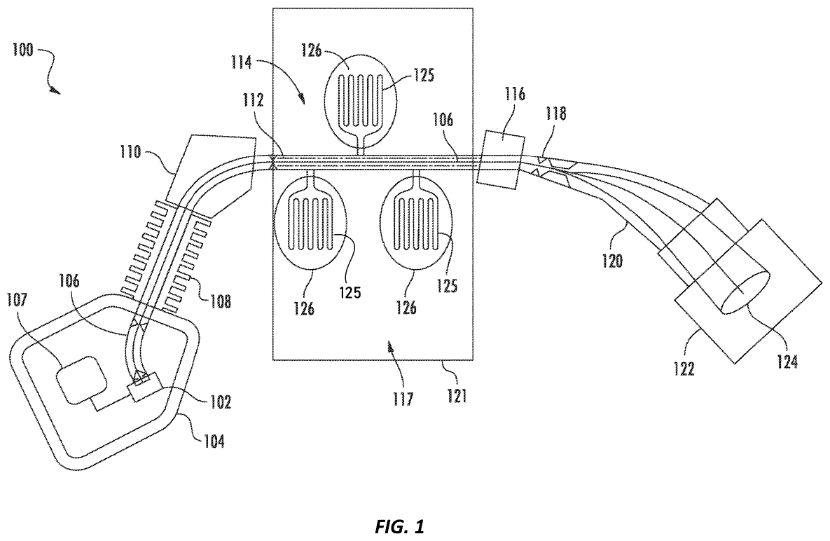

Referring now to FIG. 1, an exemplary ion implanter 100 is shown in schematic form. The ion implanter 100 may represent a beamline ion implanter, with some elements not shown for clarity and brevity of explanation. The ion implanter 100 may include an ion source 102 and a gas box 107 disposed in a terminal 104. The ion source 102 may include an extraction system including extraction components and filters (not shown) to generate an ion beam 106 at a first energy. Although non-limiting, the first ion energy may range from 5 keV to 100 keV. The ion implanter 100 may further include a DC accelerator column 108, disposed downstream of the ion source 102. The DC accelerator column 108 may be operable to accelerate the ion beam 106 to a second ion energy, where the second ion energy is greater than the first ion energy.

The ion implanter 100 may further include a mass analyzer 110 operable to analyze and filter the accelerated ion beam 106, for example, by changing the trajectory of the ion beam 106 such that only ions having desired properties continue along the path of the ion beam 106. The ion implanter 100 may also include a buncher 112 and a LINAC 114 disposed within a vacuum chamber 121. The LINAC 114 may be disposed downstream of the DC accelerator column 108 and the mass analyzer 110. The LINAC 114 may be operable to accelerate the ion beam 106 to a third energy, greater than the second energy.

The LINAC 114 may include a plurality of accelerator stages 126, each including one or more coils 125. In some embodiments, the accelerator stages 126 of the LINAC 114 may be single gap accelerator stages, while in other embodiments the accelerator stages 126 may be double gap or triple gap accelerator stages. The present disclosure is not limited in this regard. In various embodiments, the ion implanter 100 may include additional components, such as a filter magnet 116, a scanner 118, and a collimator 120, which together deliver the high-energy ion beam 106 to an end station 122 for processing a substrate 124 (e.g., a semiconductor wafer).

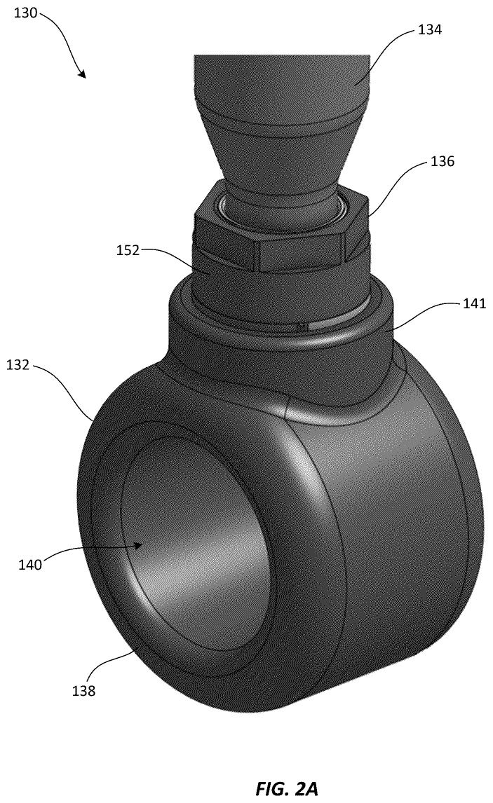

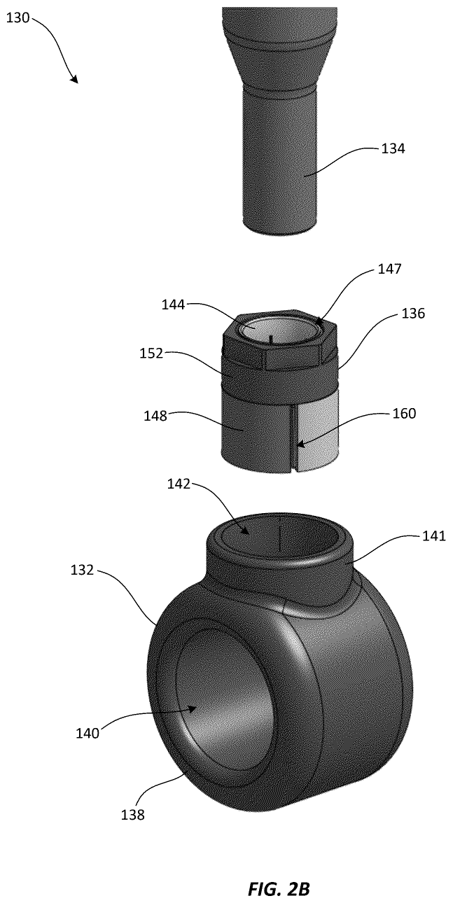

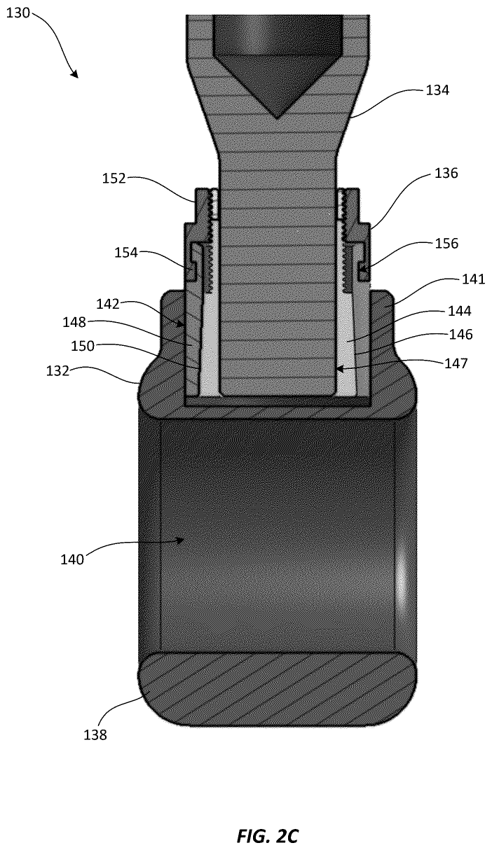

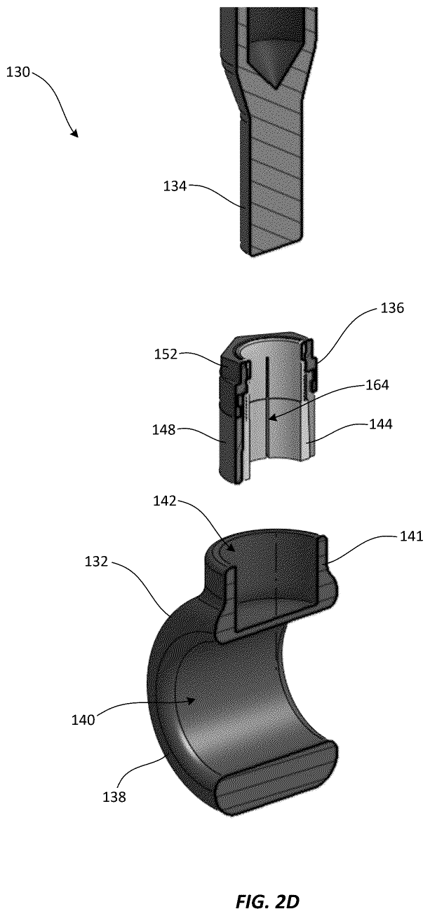

Referring to FIGS. 2A-2D, a perspective view, an exploded view, a cross-sectional view, and an exploded cross-sectional view illustrating an embodiment of a drift tube assembly 130 of the LINAC 114 (see FIG. 1) are shown, respectively. For the sake of convenience and clarity, terms such as “top,” “bottom,” “upper,” “lower,” “vertical,” “horizontal,” “lateral,” and “longitudinal,” “inner,” and “outer” may be used herein to describe the relative position and orientation of various components and features of the drift tube assembly 130, all with respect to the geometry and orientation of the drift tube assembly 130 as it appears in the views shown in FIGS. 2A-2D. Said terminology is not intended to be limiting and includes the words specifically mentioned, derivatives thereof, and words of similar import.

The drift tube assembly 130 shown in FIGS. 2A-2D is provided by way of example to illustrate an embodiment of an improved mechanical coupling for fastening components of the drift tube assembly 130 together as further described below. Those of skill in the art will appreciate that the LINAC 114 may include a plurality of drift tube assemblies with similar mechanical coupling arrangements, with one or more such drift tube assemblies located in each accelerator stage 126 of the LINAC 114. The present disclosure is not limited in this regard.

The drift tube assembly 130 may include a drift tube 132 (sometimes referred to as an “electrode”) coupled to the end of a mounting rod 134 by a mounting device 136. The drift tube 132 may include a cylindrical or annular main body 138 defining a beam aperture 140 for allowing an ion beam to pass through the drift tube 132. The drift tube 132 may further include a cylindrical mounting cuff 141 extending from a sidewall of the main body 138 and defining a round mounting socket 142 for receiving the mounting device 136 as further described below.

The mounting device 136 may be adapted to firmly secure the drift tube 132 at a desired position and orientation on the mounting rod 134. As best shown in FIG. 2C, the mounting device 136 may include a frustoconical inner sleeve 144 having a tapered exterior surface 146 and defining a passthrough 147 for receiving the mounting rod 134, a tubular outer sleeve 148 radially surrounding the inner sleeve 144 and having a tapered interior surface 150 parallel to, and radially engaging, the exterior surface 146 of the inner sleeve 144, and a nut 152 radially surrounding upper portions of the outer sleeve 148 and the inner sleeve 144 and having a radially inwardly extending flange 154 extending into a complementary annular groove 156 formed in the exterior of the outer sleeve 148. An upper portion of the exterior surface 146 of the inner sleeve 144 may be threaded and may engage a threaded, interior surface of the nut 152. As will be further described below, the threaded engagement between the nut 152 and the inner sleeve 144 may allow the inner sleeve 144 to be axially extended and retracted relative to the nut 152, while the engagement between the flange 154 of the nut 152 and the annular groove 156 of the outer sleeve 148 may allow the nut 152 to be freely rotated about its axis relative to the outer sleeve 148.

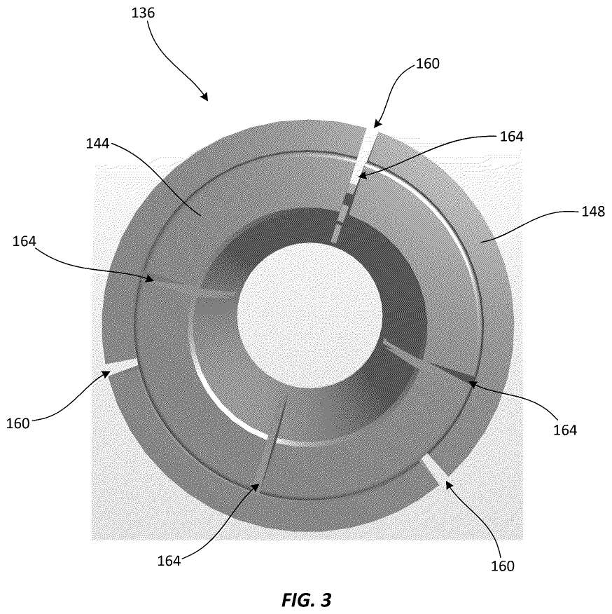

Referring to FIGS. 2B and 3, the outer sleeve 148 may include a plurality of circumferentially spaced slots 160 formed therein, wherein the slots 160 extend axially from a bottom edge of the outer sleeve 148 partially toward a top edge of the outer sleeve 148. In the example embodiment of the mounting device 136 shown in FIGS. 2B and 3, the outer sleeve 148 includes three evenly spaced slots 160 (only one of the slots 160 is visible in FIG. 2B) separating a lower portion of the outer sleeve 148 into three circumferential segments 162. The present disclosure is not limited in this regard, and alternative embodiments of the outer sleeve 148 may include a fewer or greater number of slots 160. The slots 160 may allow the circumferential segments 162 of the outer sleeve 148 to be deflected as further described below.

Referring to FIGS. 2D and 3, the inner sleeve 144 may include a plurality of circumferentially spaced slots 164 formed therein, wherein the slots 164 extend axially from a bottom edge of the inner sleeve 144 partially toward a top edge of the inner sleeve 144. In the example embodiment of the mounting device 136 shown in FIGS. 2B and 3, the inner sleeve 144 includes four evenly spaced slots 164 (only one of the slots 164 is visible in FIG. 2D) separating a lower portion of the inner sleeve 144 into four circumferential segments 166. The present disclosure is not limited in this regard, and alternative embodiments of the inner sleeve 144 may include a fewer or greater number of slots 164. The slots 164 may allow the circumferential segments 166 of the inner sleeve 144 to be deflected as further described below.

Referring to FIG. 2C, the mounting device 136 may be mounted on the end of the mounting rod 134, with the mounting rod 134 extending axially into the inner sleeve 144. The drift tube 132 may be mounted on the mounting device 136, with the mounting device extending axially into the mounting socket 142 of the mounting cuff 141 of the drift tube 132. In order to secure the drift tube 132 to the mounting rod 134 during installation, the nut 152 may be tightened (e.g., rotated clockwise), with the threaded engagement between the nut 152 and the inner sleeve 144 causing the inner sleeve 144 to be pulled upwardly relative to the nut 152 and the outer sleeve 148, and with the nut 152 rotating freely relative to the outer sleeve 148. As the inner sleeve 144 is pulled upwardly, the exterior surface 146 of the larger diameter, lower portion of the inner sleeve 144 may brought into engagement with the tapered, interior surface 150 of the outer sleeve 148, causing the inner sleeve 144 and the outer sleeve 148 to exert radially-oppositely directed forces on one another. Due to the slots 160, 164 formed in the outer sleeve 148 and the inner sleeve 144, respectively (see FIGS. 2B, 2D, and 3), these radially directed forces may cause simultaneous radial expansion of the outer sleeve 148 (i.e., radially outward deflection of the circumferential segments 162 of the outer sleeve 148) and radial contraction of the inner sleeve 144 (i.e., radially inward deflection of the circumferential segments 166 of the inner sleeve 144), resulting in simultaneous contractive tightening of the inner sleeve 144 against the mounting rod 134 and expansive tightening of the outer sleeve 148 against the mounting cuff 141. The drift tube 132 may thus be firmly secured to the mounting rod 134 in a manner that provides superior thermal coupling and resistance to relative movement compared to previous mounting arrangements involving traditional mechanical fasteners (e.g., screws, pins, friction washers, etc.).

In various embodiments, the drift tube 132, the mounting rod 134, and the mounting device 136 may be formed of the same material and may thus have the same coefficient of thermal expansion. This may prevent relative expansion and contraction of the components when heated and cooled (e.g., when subjected to ionic bombardment), which could otherwise result in misalignment of the components due to loosening of the coupling therebetween. In various embodiments, the drift tube 132, the mounting rod 134, and the mounting device 136 may be formed of a metal such as aluminum. The present disclosure is not limited in this regard.

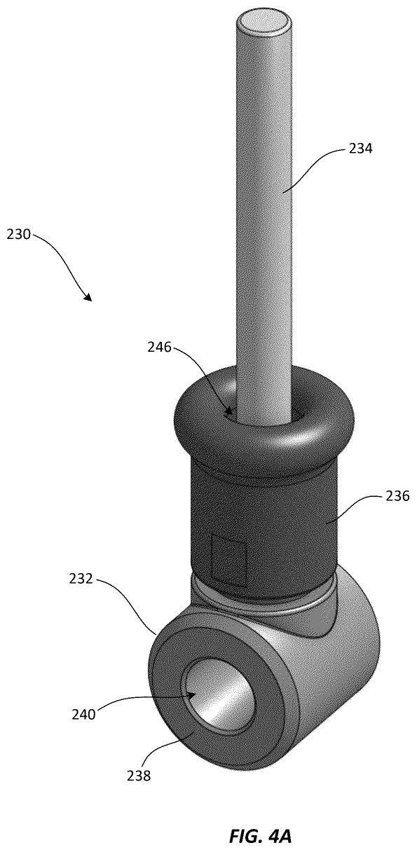

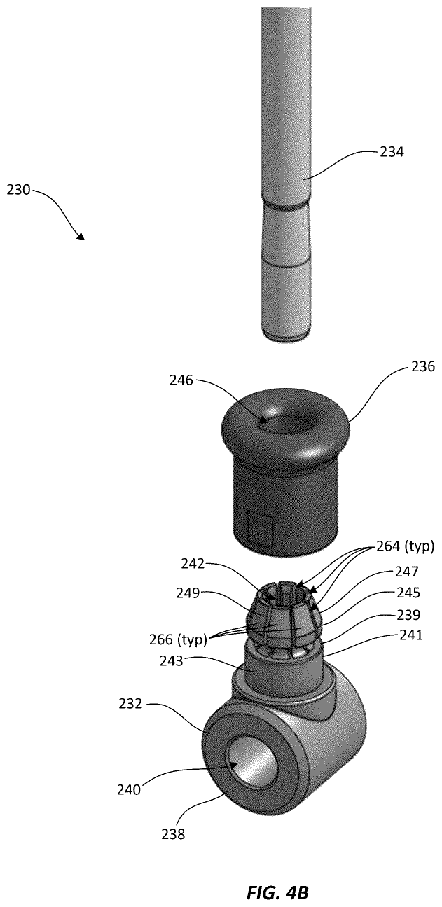

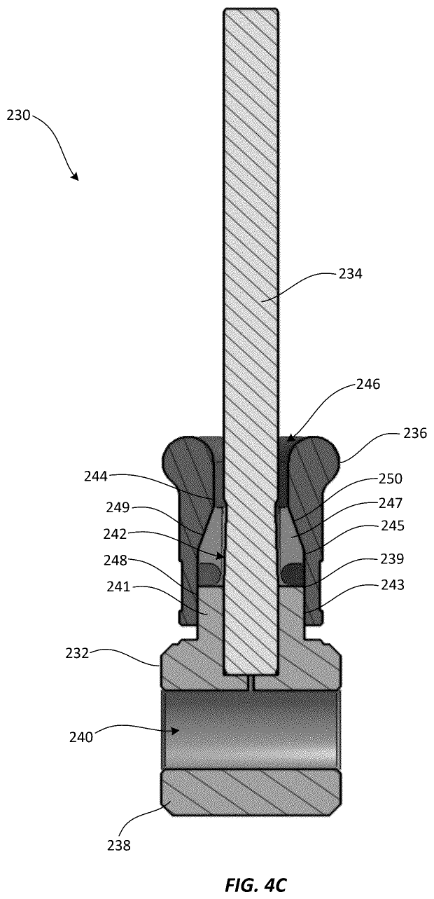

Referring to FIGS. 4A-4C, a perspective view, an exploded view, and a cross-sectional view illustrating another embodiment of a drift tube assembly 230 of the LINAC 114 (see FIG. 1) are shown, respectively. For the sake of convenience and clarity, terms such as “top,” “bottom,” “upper,” “lower,” “vertical,” “horizontal,” “lateral,” and “longitudinal,” “inner,” and “outer” may be used herein to describe the relative position and orientation of various components and features of the drift tube assembly 230, all with respect to the geometry and orientation of the drift tube assembly 230 as it appears in the views shown in FIGS. 4A-4C. Said terminology is not intended to be limiting and includes the words specifically mentioned, derivatives thereof, and words of similar import.

As with the drift tube assembly 130 described above, the drift tube assembly 230 shown in FIGS. 4A-4C is provided by way of example to illustrate an embodiment of an improved mechanical coupling for fastening components of the drift tube assembly 230 together as further described below. Those of skill in the art will appreciate that the LINAC 114 may include a plurality of drift tube assemblies with similar mechanical coupling arrangements, with one or more such drift tube assemblies located in each accelerator stage 126 of the LINAC 114. The present disclosure is not limited in this regard.

The drift tube assembly 230 may include a drift tube 232 coupled to the end of a mounting rod 234 by a mounting device 236. The drift tube 232 may include a cylindrical or annular main body 238 defining a beam aperture 240 for allowing an ion beam to pass through the drift tube 232. The drift tube 232 may further include a fastening stem 239 extending from a sidewall of the main body 238. The fastening stem 239 may include a cylindrical base portion 241 having a threaded exterior surface 243, and a generally mushroom-shaped gripping portion 245 extending from a top of the base portion 241 and having a frustoconical head 247 with a tapered exterior surface 249. The gripping portion 245 may define a round mounting socket 242 that extends through the base portion 241 and partially into the main body 238. The mounting socket 242 may be adapted to receive the mounting rod 234 in a close clearance relationship therewith as further described below.

The mounting device 236 may be adapted to firmly secure the drift tube 232 at a desired position and orientation on the mounting rod 234. As best shown in FIG. 4C, the mounting device 236 may be a generally tubular cuff having an interior surface 244 defining a passthrough 246 for receiving the mounting rod 234 and the fastening stem 239 of the drift tube 232. A lower portion 248 of the interior surface 244 may be threaded and may be adapted to threadedly engage the exterior surface 243 of the base portion 241 of the fastening stem 239. The interior surface 244 may further include a tapered portion 250 extending from a top of the lower portion 248, wherein the tapered portion 250 may be parallel to, and may radially engage, the tapered exterior surface 249 of the head 247 of the gripping portion 245 of the fastening stem 239 as further described below.

Referring to FIG. 4B, the fastening stem 239 may include a plurality of circumferentially spaced slots 264 formed therein, wherein the slots 264 extend axially from a top edge of the gripping portion 245 to a top edge of the base portion 241 of the fastening stem 239. In the example embodiment of the drift tube 232 shown in FIGS. 4A-4C, the gripping portion 245 includes eight evenly spaced slots 264 separating the gripping portion 245 into eight circumferential segments 266. The present disclosure is not limited in this regard, and alternative embodiments of the gripping portion 245 may include a fewer or greater number of slots 264. The slots 264 may allow the circumferential segments 266 of the gripping portion 245 to be deflected as further described below.

Referring to FIG. 4C, the drift tube 232 may be mounted on the end of the mounting rod 234, with the mounting rod 234 extending through the passthrough 246 of the mounting device 236 and into the mounting socket 242 of the fastening stem 239, and with the fastening stem 239 extending into the bottom of the passthrough 246 of the mounting device 236. In order to secure the drift tube 232 to the mounting rod 234 during installation, the mounting device 236 may be tightened onto the fastening stem 239 (e.g., rotated clockwise relative to the fastening stem 239), with the threaded engagement between the lower portion 248 of the interior surface 244 of the mounting device 236 and the exterior surface 243 of the base portion 241 of the fastening stem 239 causing the mounting device 236 to be lowered onto the fastening stem 239. As the mounting device 236 is tightened onto the fastening stem 239, the tapered portion 250 of the interior surface 244 may be brought into engagement with the tapered exterior surface 249 of the head 247 of the gripping portion 245 and may exert a radially-inwardly directed force on the tapered exterior surface 249. Due to the slots 264 formed in the head 247, the radially-inwardly directed force may cause radial contraction of the head 247 (i.e., radially inward deflection of the circumferential segments 266 of the head 247), resulting in contractive tightening of the head 247 onto the mounting rod 234. The drift tube 232 may thus be firmly secured to the mounting rod 234 in a manner that provides superior thermal coupling and resistance to relative movement compared to previous mounting arrangements involving traditional mechanical fasteners (e.g., screws, pins, friction washers, etc.).

In various embodiments, the drift tube 232, the mounting rod 234, and the mounting device 236 may be formed of the same material and may thus have the same coefficient of thermal expansion. This may prevent relative expansion and contraction of the components when heated and cooled (e.g., when subjected to ionic bombardment), which could otherwise result in misalignment of the components due to loosening of the coupling therebetween. In various embodiments, the drift tube 232, the mounting rod 234, and mounting device 236 may be formed of a metal such as aluminum. The present disclosure is not limited in this regard.

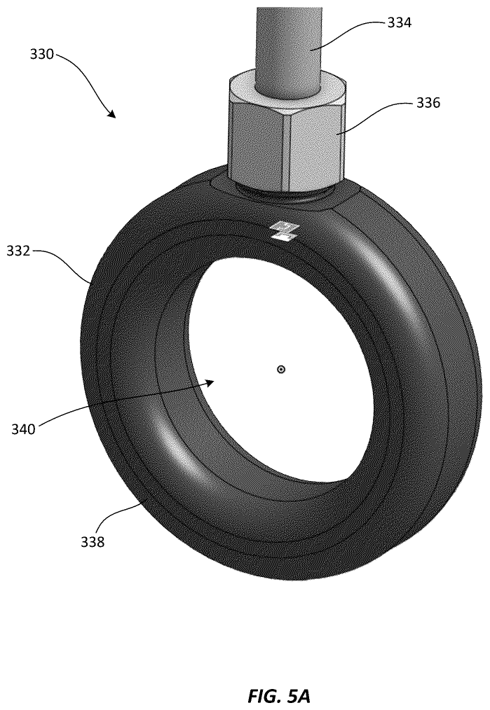

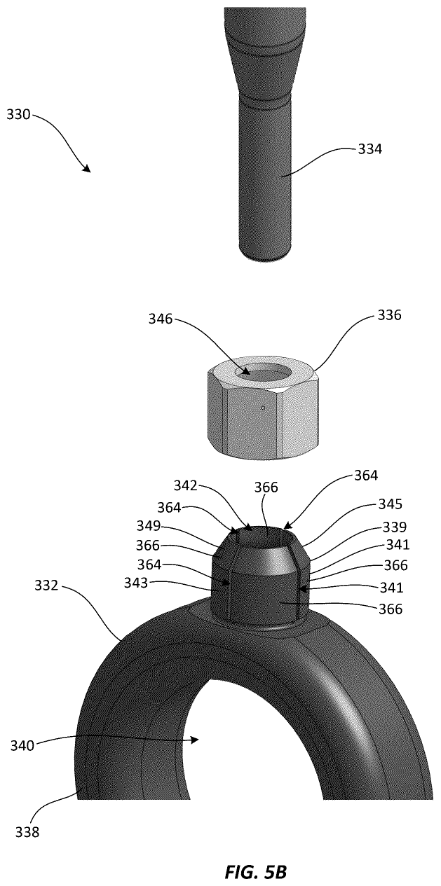

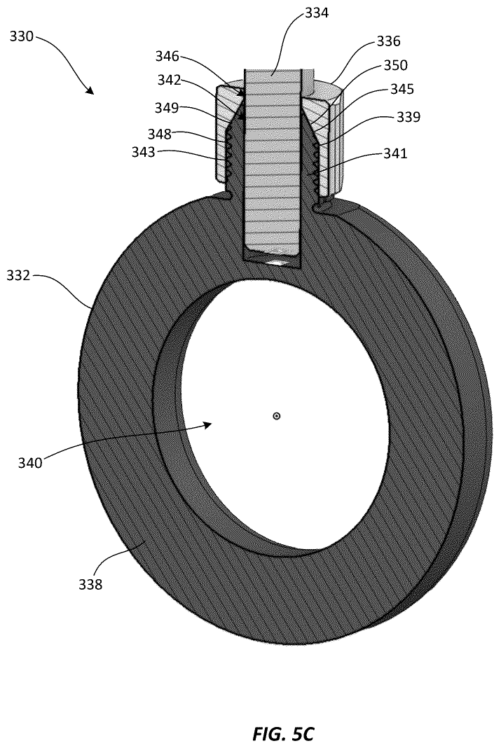

Referring to FIGS. 5A-5C, a perspective view, an exploded view, and a cross-sectional view illustrating another embodiment of a drift tube assembly 330 of the LINAC 114 (see FIG. 1) are shown, respectively. For the sake of convenience and clarity, terms such as “top,” “bottom,” “upper,” “lower,” “vertical,” “horizontal,” “lateral,” and “longitudinal,” “inner,” and “outer” may be used herein to describe the relative position and orientation of various components and features of the drift tube assembly 330, all with respect to the geometry and orientation of the drift tube assembly 330 as it appears in the views shown in FIGS. 5A-5C. Said terminology is not intended to be limiting and includes the words specifically mentioned, derivatives thereof, and words of similar import.

As with the drift tube assemblies 130 and 230 described above, the drift tube assembly 330 shown in FIGS. 5A-5C is provided by way of example to illustrate an embodiment of an improved mechanical coupling for fastening components of the drift tube assembly 330 together as further described below. Those of skill in the art will appreciate that the LINAC 114 may include a plurality of drift tube assemblies with similar mechanical coupling arrangements, with one or more such drift tube assemblies located in each accelerator stage 126 of the LINAC 114. The present disclosure is not limited in this regard.

The drift tube assembly 330 may include a drift tube 332 coupled to the end of a mounting rod 334 by a mounting device 336. The drift tube 332 may include a cylindrical or annular main body 338 defining a beam aperture 340 for allowing an ion beam to pass through the drift tube 332. The drift tube 332 may further include a fastening stem 339 extending from a sidewall of the main body 338. The fastening stem 339 may include a cylindrical base portion 341 having a threaded exterior surface 343, and a frustoconical gripping portion 345 having a tapered exterior surface 349 extending from a top of the base portion 341. The gripping portion 345 may define a round mounting socket 342 that extends through the base portion 341 and partially into the main body 338. The mounting socket 342 may be adapted to receive the mounting rod 334 in a close clearance relationship therewith as further described below.

The mounting device 336 may be adapted to firmly secure the drift tube 332 at a desired position and orientation on the mounting rod 334. As best shown in FIG. 5C, the mounting device 336 may be a nut having an interior surface 344 defining a passthrough 346 for receiving the mounting rod 334 and the fastening stem 339 of the drift tube 332. A lower portion 348 of the interior surface 344 may be threaded and may be adapted to threadedly engage the exterior surface 343 of the base portion 341 of the fastening stem 339. The interior surface 344 may further include a tapered portion 350 extending from a top of the lower portion 348, wherein the tapered portion 350 may be parallel to, and may radially engage, the tapered exterior surface 349 of the gripping portion 345 of the fastening stem 339 as further described below.

Referring to FIG. 5B, the fastening stem 339 may include a plurality of circumferentially spaced, axially extending slots 364 formed therein. In the example embodiment of the drift tube 332 shown in FIGS. 5A-5C, the fastening stem 339 includes four evenly spaced slots 364 separating the fastening stem 339 into four circumferential segments 366. The present disclosure is not limited in this regard, and alternative embodiments of the fastening stem 339 may include a fewer or greater number of slots 364. The slots 364 may allow the circumferential segments 366 to be deflected as further described below.

Referring to FIG. 5C, the drift tube 332 may be mounted on the end of the mounting rod 334, with the mounting rod 334 extending through the passthrough 346 of the mounting device 336 and into the mounting socket 342 of the fastening stem 339, and with the fastening stem 339 extending into the bottom of the passthrough 346 of the mounting device 336. In order to secure the drift tube 332 to the mounting rod 334 during installation, the mounting device 336 may be tightened onto the fastening stem 339 (e.g., rotated clockwise relative to the fastening stem 339), with the threaded engagement between the lower portion 348 of the interior surface 344 of the mounting device 236 and the exterior surface 243 of the base portion 341 of the fastening stem 339 causing the mounting device 336 to be lowered onto the fastening stem 339. As the mounting device 336 is tightened onto the fastening stem 339, the tapered portion 350 of the interior surface 344 may be brought into engagement with the tapered exterior surface 349 of the gripping portion 345 and may exert a radially-inwardly directed force on the tapered exterior surface 349. Due to the slots 364 formed in the fastening stem 339, the radially-inwardly directed force may cause radial contraction of the fastening stem 339 (i.e., radially inward deflection of the circumferential segments 366 of the fastening stem 339), resulting in contractive tightening of the fastening stem 339 onto the mounting rod 334. The drift tube 332 may thus be firmly secured to the mounting rod 334 in a manner that provides superior thermal coupling and resistance to relative movement compared to previous mounting arrangements involving traditional mechanical fasteners (e.g., screws, pins, friction washers, etc.).

In various embodiments, the drift tube 332, the mounting rod 334, and the mounting device 336 may be formed of the same material and may thus have the same coefficient of thermal expansion. This may prevent relative expansion and contraction of the components when heated and cooled (e.g., when subjected to ionic bombardment), which could otherwise result in misalignment of the components due to loosening of the coupling therebetween. In various embodiments, the drift tube 332, the mounting rod 334, and mounting device 336 may be formed of a metal such as aluminum. The present disclosure is not limited in this regard.

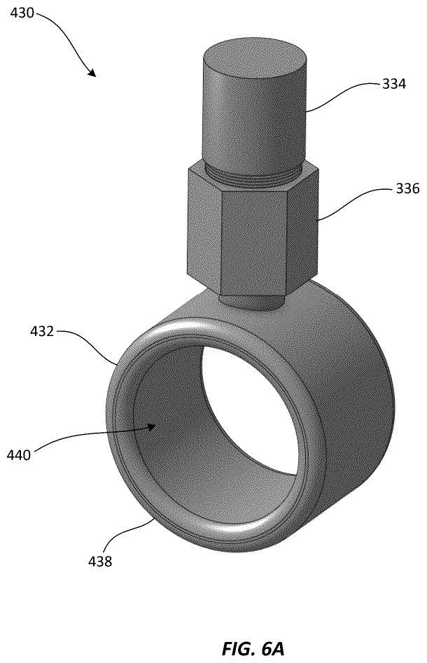

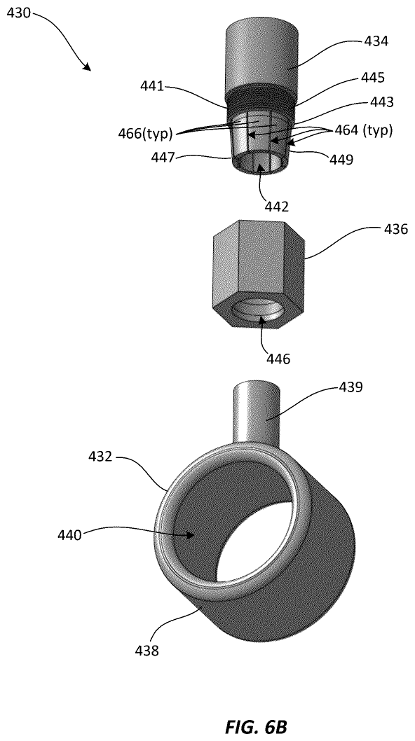

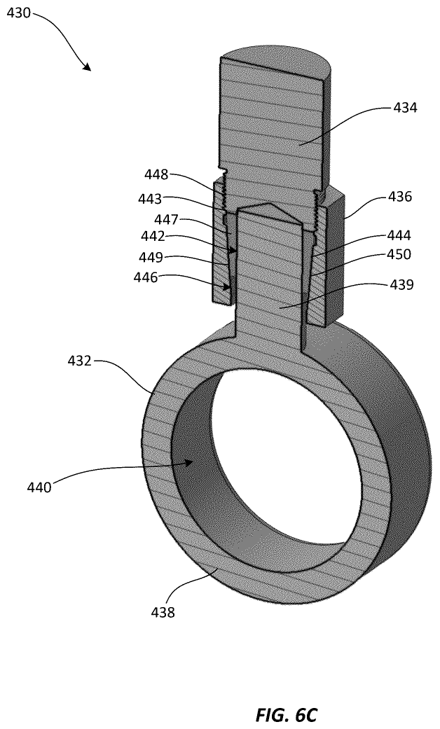

Referring to FIGS. 6A-6C, a perspective view, an exploded view, and a cross-sectional view illustrating another embodiment of a drift tube assembly 430 of the LINAC 114 (see FIG. 1) are shown, respectively. For the sake of convenience and clarity, terms such as “top,” “bottom,” “upper,” “lower,” “vertical,” “horizontal,” “lateral,” and “longitudinal,” “inner,” and “outer” may be used herein to describe the relative position and orientation of various components and features of the drift tube assembly 430, all with respect to the geometry and orientation of the drift tube assembly 430 as it appears in the views shown in FIGS. 6A-6C. Said terminology is not intended to be limiting and includes the words specifically mentioned, derivatives thereof, and words of similar import.

As with the drift tube assemblies 130, 230, and 330 described above, the drift tube assembly 430 shown in FIGS. 6A-6C is provided by way of example to illustrate an embodiment of an improved mechanical coupling for fastening components of the drift tube assembly 430 together as further described below. Those of skill in the art will appreciate that the LINAC 114 may include a plurality of drift tube assemblies with similar mechanical coupling arrangements, with one or more such drift tube assemblies located in each accelerator stage 126 of the LINAC 114. The present disclosure is not limited in this regard.

The drift tube assembly 430 may include a drift tube 432 coupled to the end of a mounting rod 434 by a mounting device 436. The drift tube 432 may include a cylindrical or annular main body 438 defining a beam aperture 440 for allowing an ion beam to pass through the drift tube 432. The drift tube 432 may further include a cylindrical fastening stem 439 extending from a sidewall of the main body 438.

A bottom end of the mounting rod 434 may terminate in a collet 443. The collet 443 may include a cylindrical base portion 441 having a threaded exterior surface 445, and a frustoconical gripping portion 447 having a tapered exterior surface 449 extending from a bottom of the base portion 441. The gripping portion 447 may define a round mounting socket 442 that extends through the collet 443 and partially into the mounting rod 434 (as best shown in FIG. 6C). The mounting socket 442 may be adapted to receive the fastening stem 439 in a close clearance relationship therewith as further described below.

The mounting device 436 may be adapted to firmly secure the drift tube 432 to the mounting rod 434 at a desired position and orientation. As best shown in FIG. 6C, the mounting device 436 may be a nut having an interior surface 444 defining a passthrough 446 for receiving the collet 443 of the mounting rod 434 and the fastening stem 439 of the drift tube 432. An upper portion 448 of the interior surface 444 may be threaded and may be adapted to threadedly engage the exterior surface 445 of the base portion 441 of the collet 443. The interior surface 444 may further include a tapered portion 450 extending from a bottom of the upper portion 448, wherein the tapered portion 450 may be parallel to, and may radially engage, the tapered exterior surface 449 of the gripping portion 447 of the collet 443 as further described below.

Referring to FIG. 6B, the gripping portion 447 of the collet 443 may include a plurality of circumferentially spaced, axially extending slots 464 formed therein. In the example embodiment of the drift tube 432 shown in FIGS. 6A-6C, the gripping portion 447 includes eight evenly spaced slots 464 separating the gripping portion 447 into eight circumferential segments 466. The present disclosure is not limited in this regard, and alternative embodiments of the gripping portion 447 may include a fewer or greater number of slots 464. The slots 464 may allow the circumferential segments 466 to be deflected as further described below.

Referring to FIG. 6C, the drift tube 432 may be mounted on the end of the mounting rod 434, with the fastening stem 439 extending through the passthrough 446 of the mounting device 436 and into the mounting socket 442 of the collet 443, and with the collet 443 extending into the top of the passthrough 446 of the mounting device 436. In order to secure the drift tube 432 to the mounting rod 434 during installation, the mounting device 436 may be tightened onto the collet 443 (e.g., rotated clockwise relative to the collet 443), with the threaded engagement between the upper portion 448 of the interior surface 444 of the mounting device 436 and the exterior surface 445 of the base portion 441 of the collet 443 causing the mounting device 436 to be raised onto the collet 443. As the mounting device 436 is tightened onto the collet 443, the tapered portion 450 of the interior surface 444 may be brought into engagement with the tapered exterior surface 449 of the gripping portion 447 and may exert a radially-inwardly directed force on the tapered exterior surface 449. Due to the slots 464 formed in the gripping portion 447 of the collet 443, the radially-inwardly directed force may cause radial contraction of the gripping portion 447 (i.e., radially inward deflection of the circumferential segments 466 of the gripping portion 447), resulting in contractive tightening of the gripping portion 447 onto the mounting rod 434. The drift tube 432 may thus be firmly secured to the mounting rod 434 in a manner that provides superior thermal coupling and resistance to relative movement compared to previous mounting arrangements involving traditional mechanical fasteners (e.g., screws, pins, friction washers, etc.). Moreover, if the drift tube 432 heats up and enlarges due to thermal expansion (e.g., when subjected to ionic bombardment), the diameter of the fastening stem 439 may expand, thus increasing the radial force (i.e., the “gripping force”) between the collet 443 and the fastening stem 439, further strengthening the coupling therebetween. The strengthened coupling also increases thermal conductivity between the collet 443 and the fastening stem 439, thus facilitating greater/more rapid cooling of the drift tube 432. The coupling thus features thermally self-regulating aspects.

In various embodiments, the drift tube 432, the mounting rod 434, and the mounting device 436 may be formed of the same material and may thus have the same coefficient of thermal expansion. This may prevent relative expansion and contraction of the components when heated and cooled (e.g., when subjected to ionic bombardment), which could otherwise result in misalignment of the components due to loosening of the coupling therebetween. In various embodiments, the drift tube 432, the mounting rod 434, and mounting device 436 may be formed of a metal such as aluminum. The present disclosure is not limited in this regard.

In sum, the embodiments of the present disclosure described above provide couplings for drift tube assemblies, wherein such couplings do not require conventional mechanical fasteners such as screws, pins, friction washers, etc. as are typically implemented in drift tube assemblies for mounting a drift tube to a mounting rod. Additionally, the above-described couplings produce strong joints (i.e., stronger than those achieved using traditional mechanical fasteners) capable of resisting external forces that could otherwise twist or translate drift tubes out of their nominal, precise positions and orientations. Still further, the above-described couplings provide superior thermal interfaces relative to traditional mechanical fasteners and thus provide superior thermal conductivity for cooling drift tubes.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

The use of “including,” “comprising,” or “having” and variations thereof herein is meant to encompass the items listed thereafter and equivalents thereof as well as additional items. Accordingly, the terms “including,” “comprising,” or “having” and variations thereof are open-ended expressions and can be used interchangeably herein.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present disclosure, and do not create limitations, particularly as to the position, orientation, or use of this disclosure. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other. Furthermore, identification references (e.g., primary, secondary, first, second, third, fourth, etc.) are not intended to connote importance or priority but are used to distinguish one feature from another.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A drift tube assembly, comprising:
a drift tube including a cylindrical main body and a mounting cuff extending from a sidewall of the main body, the mounting cuff defining a mounting socket;
a mounting device disposed within the mounting socket of the drift tube, the mounting device comprising:
a frustoconical inner sleeve having a tapered exterior surface and defining a passthrough;
a tubular outer sleeve radially surrounding the inner sleeve and having a tapered interior surface parallel to, and radially engaging, the exterior surface of the inner sleeve; and
a nut radially surrounding upper portions of the outer sleeve and the inner sleeve and including a radially inwardly extending flange extending into an annular groove formed in an exterior of the outer sleeve, the nut further having a threaded interior surface threadedly engaging a threaded upper portion of the exterior surface of the inner sleeve; and
a mounting rod extending into the passthrough of the inner sleeve of the mounting device;
wherein tightening the nut causes the inner sleeve to exert a radially-inwardly directed force on the mounting rod and causes the outer sleeve to exert a radially-outwardly directed force on the mounting cuff to couple the drift tube to the mounting rod.

2. The drift tube assembly of claim 1, wherein the outer sleeve of the mounting device includes a plurality of circumferentially spaced slots formed therein, the slots extending axially from a bottom edge of the outer sleeve partially toward a top edge of the outer sleeve, the slots separating a lower portion of the outer sleeve into a plurality of circumferential segments, and wherein the inner sleeve of the mounting device includes a plurality of circumferentially spaced slots formed therein, the slots extending axially from a bottom edge of the inner sleeve partially toward a top edge of the inner sleeve, the slots separating a lower portion of the inner sleeve into a plurality of circumferential segments.

3. The drift tube assembly of claim 2, wherein tightening the nut causes the circumferential segments of the lower portion of the outer sleeve to deflect radially-outwardly and causes the circumferential segments of the lower portion of the inner sleeve to deflect radially-inwardly.

4. The drift tube assembly of claim 1, wherein the drift tube, the mounting device, and the mounting rod are formed of the same material.

5. The drift tube assembly of claim 1, wherein the drift tube, the mounting device, and the mounting rod are formed of aluminum.

6. A drift tube assembly, comprising:
a drift tube including a cylindrical main body and a fastening stem extending from a sidewall of the main body, the fastening stem including a cylindrical base portion having a threaded exterior surface and a gripping portion extending from a top of the base portion, the gripping portion having a tapered exterior surface and defining a mounting socket;
a mounting device defining a passthrough and having an interior surface with a threaded lower portion threadedly engaging the threaded exterior surface of the base portion, the interior surface further including a tapered portion extending from a top of the lower portion, the tapered portion parallel to, and radially engaging, the tapered exterior surface of the gripping portion; and
a mounting rod extending through the passthrough of the mounting device and into the mounting socket of the gripping portion;
wherein tightening the mounting device onto the fastening stem causes the gripping portion to exert a radially-inwardly directed force on the mounting rod to couple the drift tube to the mounting rod.

7. The drift tube assembly of claim 6, the mounting device is a tubular cuff.

8. The drift tube assembly of claim 6, wherein the mounting device is a nut.

9. The drift tube assembly of claim 6, wherein the fastening stem includes a plurality of circumferentially spaced slots formed therein, the slots extending axially from a top edge of the gripping portion a top edge of the base portion and separating the gripping portion into a plurality of circumferential segments.

10. The drift tube assembly of claim 9, wherein tightening the mounting device onto the fastening stem causes the circumferential segments of the gripping portion to deflect radially-inwardly.

11. The drift tube assembly of claim 6, wherein the gripping portion is mushroom-shaped and includes a frustoconical head.

12. The drift tube assembly of claim 6, wherein the drift tube, the mounting device, and the mounting rod are formed of the same material.

13. The drift tube assembly of claim 6, wherein the drift tube, the mounting device, and the mounting rod are formed of aluminum.

14. A drift tube assembly, comprising:
a drift tube including a cylindrical main body and a fastening stem extending from a sidewall of the main body;
a mounting rod terminating in a collet, the collet including a cylindrical base portion having a threaded exterior surface and a frustoconical gripping portion extending from a bottom of the base portion, the gripping portion having a tapered exterior surface and defining a mounting socket; and
a mounting device comprising a nut defining a passthrough and having an interior surface with a threaded upper portion threadedly engaging the threaded exterior surface of the base portion, the interior surface further including a tapered portion extending from a bottom of the upper portion, the tapered portion parallel to, and radially engaging, the tapered exterior surface of the gripping portion;
wherein the fastening stem extends through the passthrough of the mounting device and into the mounting socket of the gripping portion; and
wherein tightening the mounting device onto the collet causes the gripping portion to exert a radially-inwardly directed force on the mounting rod to couple the drift tube to the mounting rod.

15. The drift tube assembly of claim 14, wherein the fastening stem includes a plurality of circumferentially spaced slots formed therein separating the gripping portion into a plurality of circumferential segments.

16. The drift tube assembly of claim 15, wherein tightening the mounting device onto the collet causes the circumferential segments of the gripping portion to deflect radially-inwardly.

17. The drift tube assembly of claim 14, wherein the drift tube, the mounting device, and the mounting rod are formed of the same material.

18. The drift tube assembly of claim 14, wherein the drift tube, the mounting device, and the mounting rod are formed of aluminum.

19. An ion implantation system comprising:
an ion source for generating an ion beam;
an end station for holding a substrate to be implanted by the ion beam; and
a linear accelerator disposed between the ion source and the end station and adapted to accelerate the ion beam, the linear accelerator comprising at least one acceleration stage including a drift tube assembly, the drift tube assembly comprising:
a drift tube including a cylindrical main body and a mounting cuff extending from a sidewall of the main body, the mounting cuff defining a mounting socket;
a mounting device disposed within the mounting socket of the drift tube, the mounting device comprising:
a frustoconical inner sleeve having a tapered exterior surface and defining a passthrough;
a tubular outer sleeve radially surrounding the inner sleeve and having a tapered interior surface parallel to, and radially engaging, the exterior surface of the inner sleeve; and
a nut radially surrounding upper portions of the outer sleeve and the inner sleeve and including a radially inwardly extending flange extending into an annular groove formed in an exterior of the outer sleeve, the nut further having a threaded interior surface threadedly engaging a threaded upper portion of the exterior surface of the inner sleeve; and
a mounting rod extending into the passthrough of the inner sleeve of the mounting device;
wherein tightening the nut causes the inner sleeve to exert a radially-inwardly directed force on the mounting rod and causes the outer sleeve to exert a radially-outwardly directed force on the mounting cuff to couple the drift tube to the mounting rod.
